(19) United States
(12) Patent Application Publication
(10) Pub. No.: US 2010/0294368 A1
(43) Pub. Date: Nov. 25, 2010

(54) PHOTOELECTRIC CONVERSION ELEMENT AND SOLAR CELL

(75) Inventors: Mayuko USHIRO, Tokyo (JP); Akihiko ITAMI, Tokyo (JP); Kazuya ISOBE, Tokyo (JP); Hideya MIWA, Tokyo (JP); Kazukuni NISHIMURA, Tokyo (JP); Hidekazu KAWASAKI, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA BUSINESS TECHNOLOGIES, INC., Tokyo (JP)

(21) Appl. No.: 12/779,284

(22) Filed: May 13, 2010

(30) Foreign Application Priority Data
May 22, 2009 (JP) 2009124002

(51) Int. Cl. H01L 51/46; H01L 51/44

(52) U.S. Cl. 136/263; 257/40; 257/E51.041

(57) ABSTRACT

A photoelectric conversion element having a semiconductor layer and a charge transfer layer provided between a first electrode and a second electrode is disclosed, and the semiconductor layer has light absorption in an absorption wavelength region at least 350 to 1,000 nm and has light transmission in the absorption wavelength region of the semiconductor, the charge transfer layer comprises a charge transfer complex formed by an electron-donating compound and an electron-accepting compound, and the charge-transfer complex has an absorption wavelength in the transmission wavelength of the semiconductor layer.

This application is based on Japanese Patent Application No. 2009-124002 filed on May 22, 2009, in Japanese Patent Office, the entire content of which is hereby incorporated by reference.

### TECHNICAL FIELD

The present invention relates to a photoelectric conversion element and in particular to a dye-sensitized photoelectric element and a solar cell by use thereof.

### TECHNICAL BACKGROUND

In recent years, there has been energetically studied employment of solar light which is inexhaustible and causes no toxic material. Practical uses of solar light as a clean energy source include inorganic solar cells for residential use, such as a single crystalline silicon, a polycrystalline silicon, made of an amorphous silicon, cadmium telluride, and indium selenide.

Shortcomings of inorganic solar cells, for example, are that silicon solar cells require extremely high purity is required, which complicates purification process and results in enhanced production cost.

On the other hand, there are a number of solar cells employing organic material. Organic solar cells include a Schottky type photoelectric conversion element in which a p-type organic semiconductor and a metal exhibiting a small work function are joined, and a hetero junction type photoelectric conversion element in which a p-type organic semiconductor and an n-type inorganic semiconductor, or a p-type organic semiconductor and an electron-accepting organic compound are joined. There are employed organic semiconductors such as chlorophyll, synthetic dyes and pigments, e.g., perylene, electrically conductive polymeric materials and their composite materials. These materials are thin-layered through a vacuum deposition, casting or dipping method to constitute cell materials. Organic materials have advantages such as low-cost and large dimensions being readily achieved but also have problems in that almost all of them exhibit a conversion efficiency of not more than 1% and their durability is inferior.

In such a situation, a solar cell exhibiting superior characteristics was reported in (see, for example, B. O'Regan & M. Gratze, Nature, 353, 737 (1991)). The proposed cell is a dye-sensitized solar cell and is also a wet solar cell having a working electrode of a porous titanium oxide thin-layer, spectrally sensitized with a ruthenium complex. Further a coupling and conjunction treatment of oxide semiconductor particles mutually is conducted to improve electric conductivity by enhancing contact of the oxide semiconductor. Advantages of this system are that it is not necessary to purify a low-priced metal compound semiconductor such as titanium oxide to high purity so that it is low-cost and can employ lights extending over the broad visible region and a solar light having a large visible light content can be effectively converted to electricity. However, the wet solar cell using liquid electrolyte has a problems of less reliability and less long time stability in view of volatilization and leakage of electrolytic solution, or release of sensitizing dye when it is used for long time. A solid dye-sensitized solar cell using a solid electrolytic material containing a hole transfer material is proposed to dissolve these problem (see, for example, JP A 2007-115665).

Besides it is reported that a charge transfer material using a charge-transfer complex containing a material having fluorenone side chain is suitable for a charge transfer material for a hole transfer material of an organic EL material, a solar cell and so on (see, Japan Patent No. 4173482). However, a high photoelectric conversion efficiency was not obtained because sufficient mobility was not obtained in the solar cell which is an element no voltage is applied from outside, by only employing the charge transfer complex for the charge transfer layer of the dye sensitized solar cell. Further there are problems that it is liable to accumulate carrier inside of the element, progress deterioration at dark time, particularly low stability under the active gas environment in case of photoelectric conversion element exhibiting sufficient mobility.

### SUMMARY OF THE INVENTION

An object of this invention is to provide a photoelectric conversion element having high durability and a high photoelectric conversion efficiency, and a solar cell employing it.

The object described above can be attained as follows.

A photoelectric conversion element comprising a semiconductor layer having absorption in a wavelength region at least 350 to 1,000 nm and a charge transfer layer between opposing a first electrode and a second electrode, wherein the semiconductor layer has transmission wavelength in the wavelength region, the charge transfer layer comprises a charge transfer complex formed by an electron-donating compound and an electron-accepting compound, and the charge-transfer complex has absorption wavelength in the transmission wavelength of the semiconductor layer.

A transmittance of the semiconductor layer at the transmission wavelength is preferably not less than 40%.

In the photoelectric conversion element, a molar concentration ratio of the electron-donating compound to the electron-accepting compound forming the charge transfer complex is preferably;

electron-donating compound/electron-accepting compound=20/1 to 5/1.

A solar cell of this invention contains the photoelectric conversion element.

### BRIEF DESCRIPTION OF DRAWING

FIG. 1 is a sectional view of a photoelectric conversion element of this invention.

FIG. 2 is a sectional view of another photoelectric conversion element of this invention.

FIG. 3 is a chart showing transmission of the semiconductor used in this invention.

FIG. 4a shows absorption spectra of the electron-donating compound, the electron-accepting compound and the electron charge transfer complex, and FIG. 4b shows the difference of these spectra.

### DESCRIPTION OF THE INVENTION

A photoelectric conversion element having high durability and a high photoelectric conversion efficiency, and a solar cell employing it can be provided according to this invention.

The best embodiment to practice this invention is described below.

It has been found that sufficient photoelectric conversion efficiency is not obtained because number of carriers in the solid electrolyte is not sufficient and conductivity is low as a result of a study of the reason of low photoelectric conversion efficiency of the conventional dye sensitized photoelectric conversion element employing solid electrolyte by the inventor. Though a method has been known in which hole dope agent is added to increase number of carriers, durability is lowered because unstable cation radical always exist by this method. It has been found that an element exhibiting excellent photoelectric conversion property can be provided by employing a charge-transfer complex formed by two kinds of compounds in the charge transfer layer bearing a function of an electrolyte, and the charge-transfer complex is excited by light whereby a number of transfer carriers are increase. The charge transfer complex requires excitation by light to increase number of carriers of the charge transfer complex by light, and practically it can be attained by that an absorption wavelength region of the charge transfer complex is exposed to light. Therefore, the conventional method to add simply a charge transfer complex does not display sufficient charge transfer ability because the semiconductor layer absorbs light, absorption region of the charge transfer complex is not exposed and increase of number of carriers does not occur.

Conductivity is improved by increasing number of carriers by virtue of light excited carrier in this invention, different from the photoelectric element to which hole doping agent is added, therefore, cation radical does not exist when it is not exposed to light, continuous hole doping is possible and efficiency does not lower for long time use in addition that durability does not lower.

### <<Photoelectric Conversion Element>>

The photoelectric conversion element of this invention is described with reference to drawing.

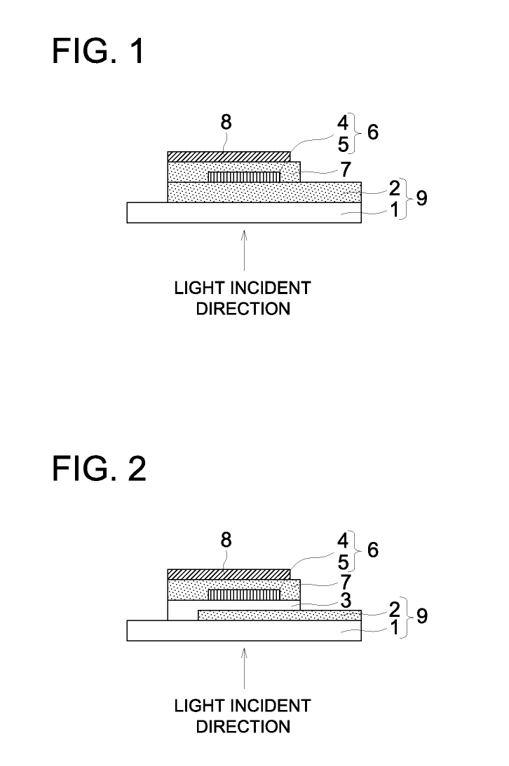

FIG. 1 is a sectional view of an example of a photoelectric conversion element of this invention. The photoelectric conversion element of this invention is composed of substrate 1, transparent conductive layer 2, semiconductor layer 6, charge transfer layer 7, and second electrode 8 and so on.

An example of a manufacturing method of the photoelectric conversion element of this invention will be described below.

On a transparent substrate 1 provided with a first electrode 9 and transparent conductive layer 2 insulating layer 3 is formed if necessary, then semiconductor 5 having pores formed by sintering, surface of the pores is allowed to absorb dye 4 to form a semiconductor layer 6. Charge transfer layer 7 comprising an electron-donor compound and an electron-accepting compound is provided on the semiconductor layer 6, and further second electrode 8 is provided. Electric terminals are attached to the first electrode 9 and the second electrode 8 to take out photo electric current in this instance. Sectional view of an element having an insulating layer is shown by FIG. 2.

### (Semiconductor Layer)

A manufacturing method of semiconductor layer 6 according to this invention is described.

The semiconductor layer 6 according to this invention is composed of semiconductor, a dye and, an additive, if necessary.

The semiconductor layer absorbs light by semiconductor, a dye or their aggregate in wavelength region of 350 to 1,000 nm. It is desirable that the semiconductor layer absorbs light energy as wide as possible, and transmittance of the semiconductor layer is preferably less than 40%, more preferably 2 to 35%, further preferably 2 to 20%. In case absorbing light so high as the transmittance of lower than 2%, conversion efficiency may lower to the contrary, because number of carriers generation increases and generated electron is difficult to take out to electrode in comparison with high transparency when the photoelectric conversion element is operated in high temperature circumstances. It is preferable that the sensitizing treatment by employing dye such as adsorption and enclosure into pores is conducted after the sintering semiconductor, when the semiconductor is prepared by sintering. It is particularly preferable to conduct the adsorption treatment rapidly prior to water is adsorbed to the semiconductor.

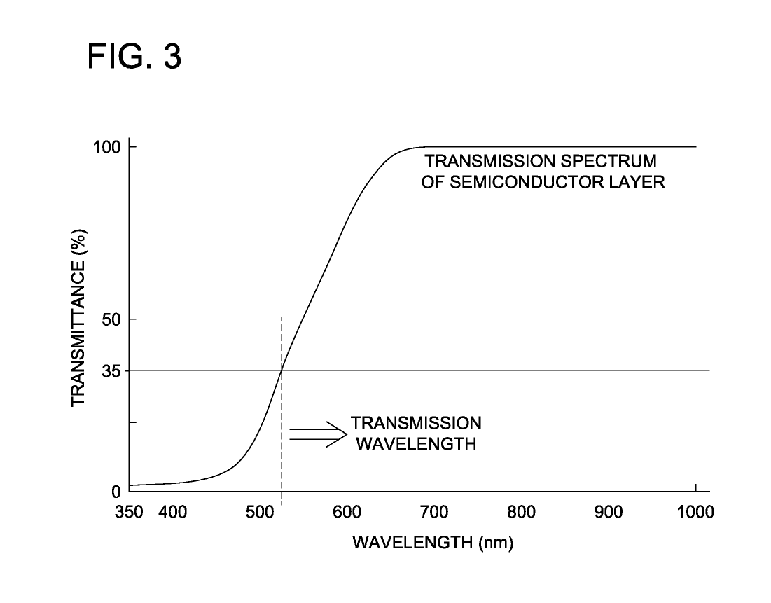

The semiconductor layer has transmission wavelength in wavelength region of 350 to 1,000 nm, as shown in FIG. 3, in this invention. The transmission wavelength means wavelength at which the transmittance of the semiconductor layer is 35%. Preferable range of the transmittance is 40 to 95% and more preferably 55 to 95%, and further preferably 75 to 95%. Dye molecule having transmission wavelength in this wavelength region or its aggregate is adsorbed to the semiconductor so that the semiconductor layer has the transmission wavelength.

It is preferable that the semiconductor layer is manufactured by coating or spraying the semiconductor on the conductive support in case that the semiconductor according to this invention is shape of particles. It is preferable to manufacture the semiconductor layer by covering the semiconductor film on the conductive support in case that the semiconductor according to this invention is shape of a film and is not maintained on the conductive support.

Semiconductors usable in the photoelectrode include simple substances such as silicon and germanium, compounds containing elements of Groups 3-5 and 13-15 of the periodical table, metal chalcogenides (e.g., an oxides, a sulfide, a selenide) and metal nitrides.

Preferred metal chalcogenides include an oxide of titanium, tin, zinc, iron, tungsten, zirconium, hafnium, strontium, indium, cerium, yttrium, lanthanum, vanadium, niobium or tantalum; a sulfide of cadmium, zinc, lead, silver, antimony or bismuth; a selenide of cadmium or lead; and a telluride of cadmium. Other semiconductors include a phosphide of zinc, gallium, indium or cadmium; a gallium-arsine or copper-indium selenide; a copper-indium sulfide and a titanium nitride.

Specific examples include TiO₂, ZrO₂, SnO₂, Fe₂O₃, WO₃, ZnO, Nb₂O₅, Ta₂O₅, CdS, ZnS, PbS, Bi₂S₃, CdSe, CdTe, GaP, InP, GaAs, CuInS₂, CuInSe₂ and Ti₃N₄. Of these, TiO₂, ZnO, SnO₂, Fe₂O₃, WO₃, Nb₂O₅, CdS and PbS are preferred, TiO₂ and Nb₂O₅ are more preferred and TiO₂ is specifically preferred.

Plural semiconductors may be used in combination for the photoelectrode. For instance, plural kinds of the foregoing metal oxides or metal sulfides may be used in combination, or a titanium oxide semiconductor may be mixed with 20% by weight of titanium nitride (Ti₃N₄). There may also be used a zinc oxide/tin oxide composite, as described in J. Chem. Soc., Chem. Commun., 15 (1999). In that case, when incorporating an additional semiconductor component other than the metal oxide or metal sulfide, the additional component is incorporated preferably in an amount of not more than 30% by mass of the metal oxide or metal sulfide.

### (Preparation of Semiconductor Powder-Containing Coating Composition)

First, a semiconductor powder-containing coating composition is prepared. The primary particle diameter of this semiconductor powder is preferably as fine as possible. The semiconductor powder preferably has a primary particle diameter of 1-5,000 nm, and more preferably has a primary particle diameter of 2-50 nm. The coating composition containing the semiconductor powder can be prepared by dispersing the semiconductor powder in a solvent. The semiconductor powder dispersed in the solvent is dispersed in the form of the primary particle. The solvent is not specifically limited as long as it can disperse the semiconductor powder.

As the foregoing solvent, water, an organic solvent, and a mixture of water and an organic solvent are included. As the organic solvent, alcohol such as methanol, ethanol or the like, ketone such as methyl ethyl ketone, acetone, acetylacetone, or the like and hydrocarbon such as hexane, cyclohexane or the like are usable. A surfactant and a viscosity controlling agent (polyhydric alcohol such as polyethylene glycol or the like) can be added into a coating composition, if desired. The content of the semiconductor powder in the solvent is preferably 0.1-70% by weight, and more preferably 0.1-30% by weight.

### (Coating of Semiconductor Powder-Containing Coating Composition and Calcination Treatment of Formed Semiconductor Layer)

The semiconductor powder-containing coating composition obtained as described above is coated or sprayed onto the conductive support, followed by drying, and then calcined in air or inactive gas to form a semiconductor layer (referred to also as a semiconductor film) on the conductive support.

The layer formed via coating the semiconductor powder-containing coating composition onto the conductive support, followed by drying is composed of an aggregate of semiconductor particles, and the particle diameter corresponds to the primary particle diameter of the utilized semiconductor powder.

The semiconductor particle aggregated layer formed on a conductive layer of the conductive support or the like in such the way is subjected to a calcination treatment in order to increase mechanical strength and to produce a semiconductor layer firmly attached to a substrate, since the semiconductor particle layer exhibits bonding force with the conductive support, as well as bonding force between particles, and also exhibits weak mechanical strength.

In the present invention, this semiconductor layer may have any structure, and a porous structure layer (referred to also as a porous layer possessing pores) is preferable.

The semiconductor layer preferably has a porosity of 10% by volume or less, more preferably has a porosity of 8% by volume or less, and most preferably has a porosity of 0.01 to 5% by volume. The porosity of the semiconductor layer means a through-hole porosity in the direction of thickness of a dielectric, and it can be measured by a commercially available device such as a mercury porosimeter (Shimadzu Poresizer 9220 type) or the like.

A semiconductor layer as a calcined film having a porous structure preferably has a thickness of at least 10 nm, and more preferably has a thickness of 100 to 10,000 nm.

A calcination temperature of 1,000° C. or less is preferable, a calcination temperature of 200-800° C. is more preferable, and a calcination temperature of 300 to 800° C. is still more preferable in view acquisition of a calcined film having the above-described porosity by suitably preparing real surface area of the calcined film during calcination treatment.

A ratio of the real surface area to the apparent surface area can be controlled by a diameter and specific surface area of the semiconductor particle, the calcination temperature and so forth. After conducting a heat treatment, chemical plating employing an aqueous solution of titanium tetrachloride or electrochemical plating employing an aqueous solution of titanium trichloride may be conducted in order to increase the surface area of a semiconductor particle and purity in the vicinity of the semiconductor particle, and to increase an electron injection efficiency from a dye to a semiconductor particle.

### (Dye)

A dye to be allowed to adsorb to the semiconductor according to this invention is required that the semiconductor layer adsorbed by the dye has transmission wavelength at wavelength region of 350 to 1,000 nm. It is preferable to have the absorption at the same wavelength region. The above mentioned dye has preferably a carboxyl group in view of effective injection of charge into semiconductor. Practical examples of the dye are listed, but the present invention is not limited to these.

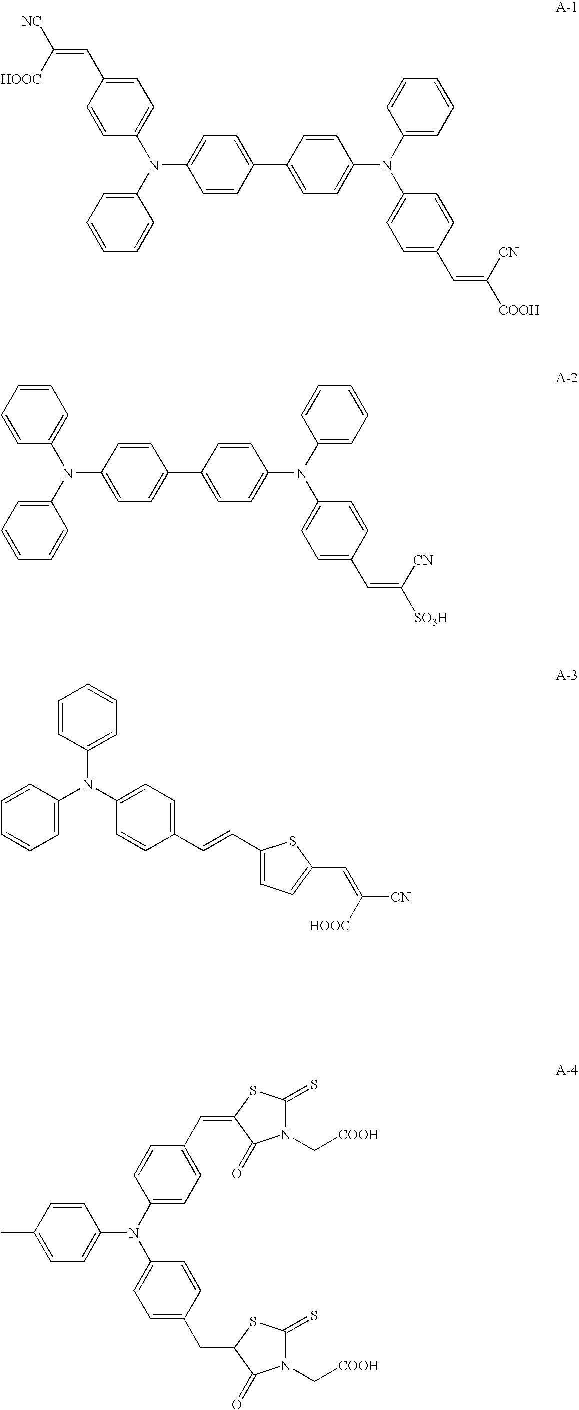

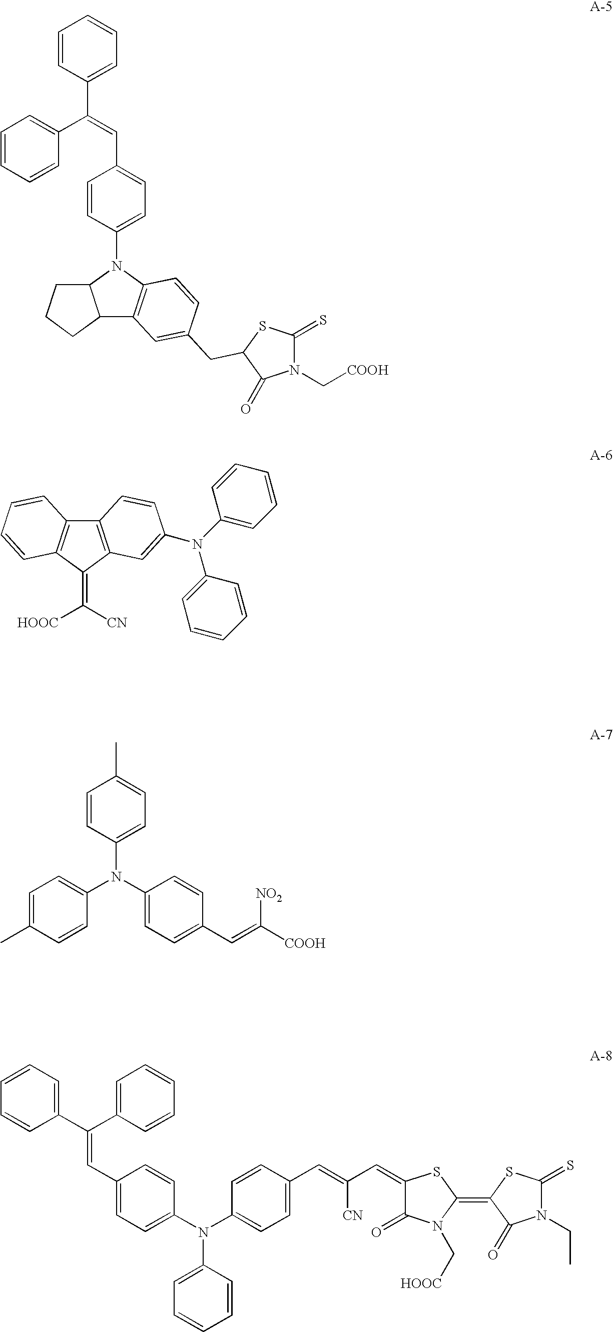

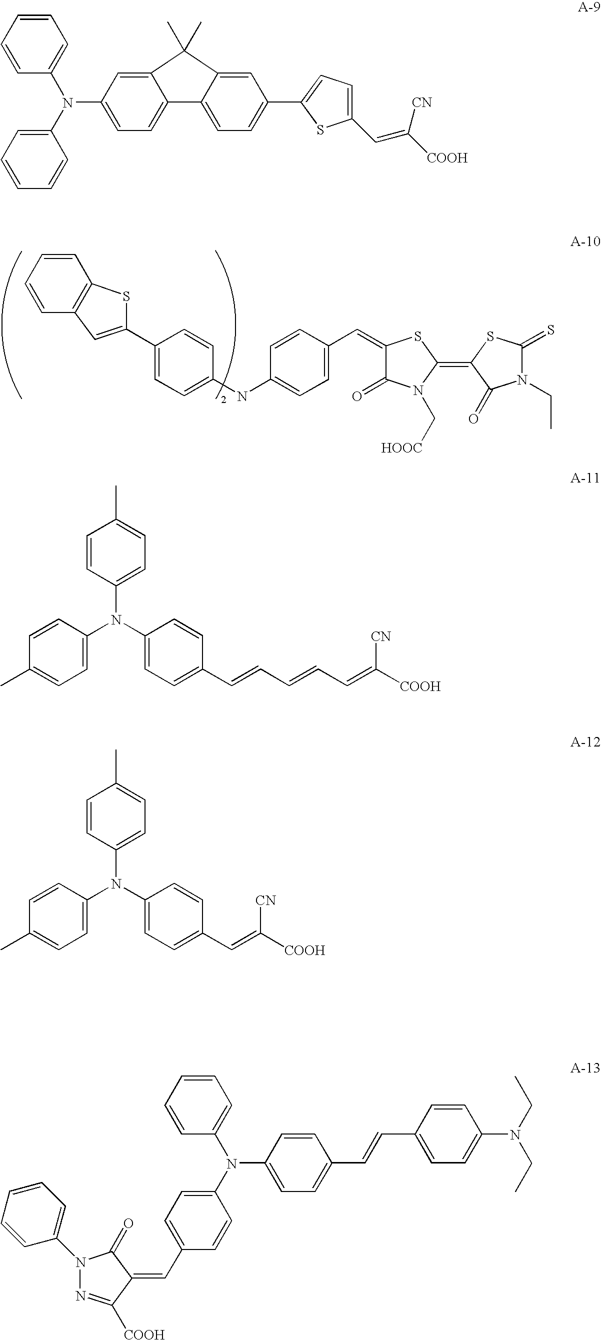

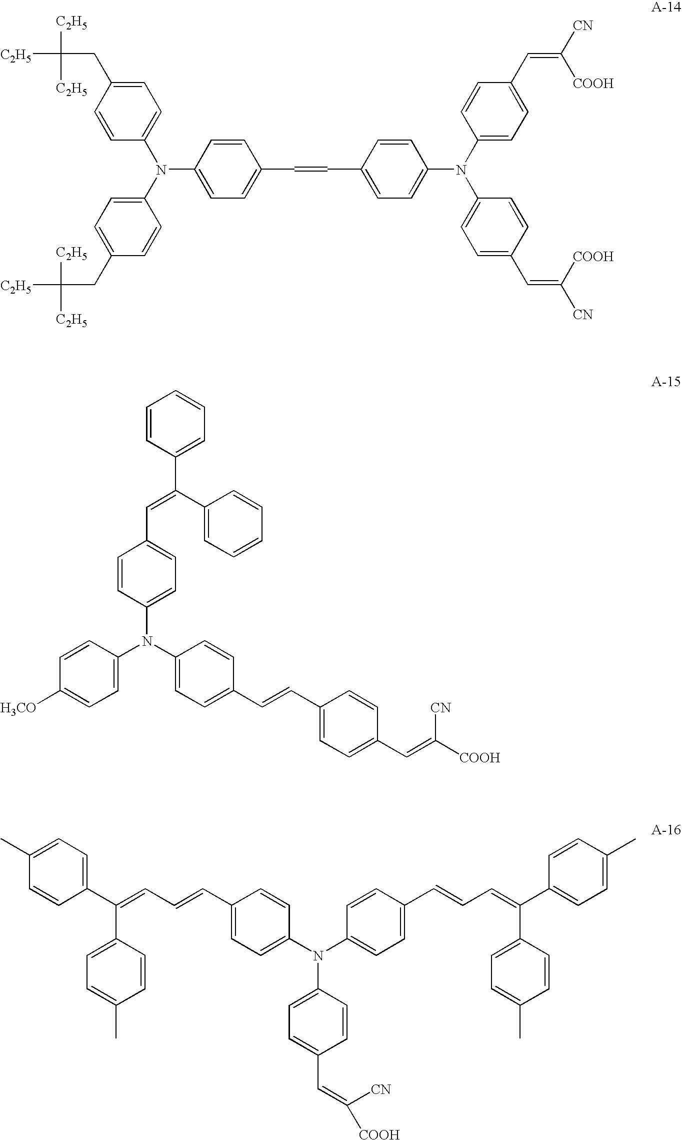

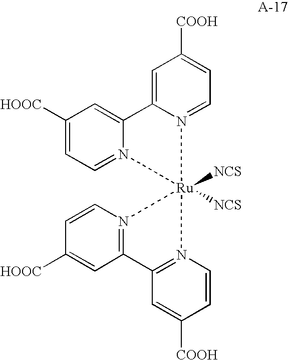

### (Sensitization Treatment of Semiconductor)

The sensitization treatment of the semiconductor is carried out by immersing a substrate calcined with the foregoing semiconductor into a solution prepared after dissolving a sensitizing dye in a suitable solvent as described before. In this case, bubbles in the layer are preferably removed by conducting a reduced pressure treatment or a heat treatment for a substrate on which a semiconductor layer is formed via calcination. Through such the treatment, a sensitizing dye can easily be penetrated deeply into the inside of the semiconductor layer, and such the treatment is specifically preferable when the semiconductor layer possesses a porous structure film. It is preferable to complete the absorption treatment of the sensitizing dye (sensitizing treatment of the semiconductor) prior to absorption of water within pores at the surface or inside of the semiconductor by water, vapor or so in case of the semiconductor having high porosity.

The solvent to dissolve the foregoing sensitizing dye is not specifically limited as long as the solvent can dissolve the foregoing co The solvent is preferably subjected to deaeration and purification via distillation to prevent penetration of moisture and gas dissolved in the solvent into the semiconductor layer so as to avoid the sensitization treatment such as adsorption of the foregoing compound or the like.

Examples of preferably usable solvents to dissolve the foregoing compound include an alcohol solvent such as methanol, ethanol, n-propanol and t-butyl alcohol; a ketone solvent such as acetone and methylethyl ketone; an ether solvent such as diethyl ether, diisopropyl ether, tetrahydrofuran and 1,4-dioxane; a nitrile solvent such as acetonitrile and propionitrile; and a halogenated hydrocarbon solvent such as methylene chloride, and 1,1,2-trichloroethane, and mixture thereof can be used. Specifically preferred are methanol, ethanol, t-butyl alcohol, acetonitrile, tetrahydrofuran, toluene and mixture of these.

As to time to immerse a substrate on which the semiconductor layer is formed via calcination in a solution containing a sensitizing dye of the present invention, it is preferable to sufficiently sensitize the semiconductor by sufficiently making progress of adsorption by penetrating deeply into the semiconductor layer. The time is preferably 1 to 48 hours, and more preferably 3 to 24 hours at 25° C. in order to inhibit that decomposed products prepared via decomposition of a sensitizing dye in a solution obstruct adsorption of the sensitizing dye formed by decomposition of the dye in the solvent. This effect is remarkable when the semiconductor film is specifically a porous structure film. The immersion time is that at 25° C. and is not always applied when the temperature is varied.

During the immersion, a solution containing a sensitizing dye employed in the present invention may be heated up to the temperature of no boiling, as long as the foregoing sensitizing dye is not decomposed. The temperature range is preferably 10 to 100° C., and more preferably 25 to 80° C., as long as the solution is not boiled in the foregoing temperature range.

The absorption treatment may be conducted when the semiconductor is particle state or after forming a layer on the substrate. The absorption of dye may be conducted by coating the semiconductor fine particles and the sensitizing dye simultaneously. Unabsorbed dye can be removed by washing.

Dye may be used singly or two or more dyes maybe used in combination for the sensitization by employing dyes.

A dye having carboxyl group preferably used in this invention may be used in combination with other dye. The dye used in combination includes any dyes which can sensitize the semiconductor of this invention. It is preferable to use those making the wavelength of photoelectric conversion as broad as possible, and to mix two or more dyes to enhance the photoelectric conversion efficiency. Species and content ratio of the dyes can be selected to adapt the wavelength and intensity distribution of the objective light source.

It is preferable to use two or more dyes having different absorption wavelength each other in combination so as to utilize sun light effectively by broadening the wavelength of photoelectric conversion as wide as possible in case the photoelectric conversion element of this invention is used for a solar cell as described later.

Among the dyes for mixing used, a metal complex dye, a phthalocyanine dye, a porphyrin dye and a polymethine dye are preferably used from the comprehensive viewpoint such as photoelectron transfer reactivity, fastness against light and photochemical stability.

Examples of the dyes used in combination with preferable dyes having a carboxyl group in this invention include those disclosed in U.S. Pat. No. 4,684,537, U.S. Pat. No. 4,927,721, U.S. Pat. No. 5,084,365, U.S. Pat. No. 5,350,644, U.S. Pat. No. 5,463,057, U.S. Pat. No. 5,525,440, JP-A H07-249790, and JP-A 2000-150007.

Each dye can be used by preparing solution of mixture of each dye, or immersing into each dye solution prepared respective in sequence, when plural dyes are used or dyes are used in combination with preferable dyes having a carboxyl group in this invention.

### (Charge Transfer Layer)

The solid type dye sensitized solar cell, in which electric junction between the first electrode and the second electrode is conducted by solid electrolyte, has a problem that a photo-electric conversion efficiency is very low. The reason is estimated that a number of carriers in the solid electrolyte are insufficient and electro conductivity is low. When a hole dope agent is added so as to increase a number of carriers, durability is deteriorated because unstable cation radical always exists.

Therefore, the charge transfer layer working as an electrolyte employs two kinds of compounds which form a charge transfer complex having an absorption in a region which does not overlap the absorption region of the semiconductor layer in this invention. In detail, a semiconductor layer and a charge transfer layer are employed, wherein the semiconductor layer has transmittance of 35% or more in a wavelength region of 350 to 1,000 nm; and the charge transfer layer comprises a charge-transfer complex formed by an electron-donating compound B and an electron-accepting compound C, and the charge-transfer complex has an absorption at least in the transmission wavelength.

The charge-transfer complex is formed in the charge transfer layer by allowing the electron-donating compound and the electron-accepting compound to exist simultaneously in a system. A molar ratio of mixing the electron-donating compound and the electron-accepting compound is preferably electron-donating compound/electron-accepting compound=20/1 to 5/1. It is possible that the absorption of the charge transfer complex becomes weak, sufficient amount of carriers does not generate, and improvement of conductivity is not obtained sufficiently when the ratio of the electron-donating compound increases to exceed the above described range. It is possible that number of carriers increased too much, rate to reduce the oxidized dye becomes slow and the conversion efficiency of the photo-electric conversion element becomes lower when the ratio of the electron-donating compound is fewer than the above described range.

The electron-donating compound is a compound that is stable when it donates an electron, and showing ionization potential (Ip) measured by an atmospheric photoelectron spectrometer (trade name of AC-3, manufactured by Riken Keiki Co., Ltd.). A preferable IP range is 4.7 to 5.8 eV, and more preferably 4.8 to 5.5 eV. The electron-donating compound is preferable electron-rich in a molecular structure. Examples include those having a substituted or non-substituted amine group, a hydroxy group, an ether group, a sulfur atom and so on, in π electron system of the molecule. Practically compounds such as phenyl amines, triphenyl methanes, carbazoles, phenols, and tetrathiafulvalenes are listed.

The electron-accepting compound is a compound that is stable when it receives an electron. The electron-accepting compound is preferably insufficient electrons in the molecular structure. Examples include those having an electron attractive substituent such as a nitro group, cyano group, carboxyl group and a halogen group in π electron system of the molecule, and practically, quinines, fluorenones, chloranils, bromanils, and tetracyanoquinodimethanes are listed.

A method to determine absorption of the electron charge transfer complex is described. Among the absorption spectra of the electron-donating compound and the electron-accepting compound, the absorption spectrum of a compound having the absorption maximum (λₘₐₓ) at the short wave side is defined as S1, the absorption spectrum of a compound having the absorption maximum (λₘₐₓ) at the long wave side is defined as S2, and the absorption spectrum of the charge transfer layer formed by mixing the absorption spectra of the electron-donating compound and the electron-accepting compound is defined as S3.

S3 can be measured by serving the charge transfer layer of the element. S1 and S2 can be measured from the compound obtained by extraction and separation of each compound from the electron charge transfer layer. Spectra S1 and S2 are measured by, for example, a method in which a thin film sample prepared by that solution or dispersion dissolving or dispersing the compound is coated on a slide glass and dried and the transmission spectrum is measured.

<<Determining method having skirt of S2 at shorter wave side than λₘₐₓ of S1>>

Arbitral two wavelength λ1 and λ2(nm) are selected in a wavelength region having S2 skirt at shorter wave side than λₘₐₓ of S1, and respective absorbance S1(λ1), S1(λ2), S2(λ1) and S2(λ2) are measured.

A mixture ratio of the electron-donating compound to the an electron-accepting compound is calculated absorbance S3(λ1) and S3(λ2) of S3 at two wavelength of λ1 and λ2 (nm). The calculation formulae are as follows.

The values α and β are determined by the formulae,

S3(λ1)=αS1(λ1)+βS2(λ1), S3(λ2)=αS1(λ2)+βS2(λ2)

Then, it is decided that a charge transfer complex is formed, when a region not to be 0 is remained at a wavelength region having no semiconductor absorption by the mixture of S1 and S2 from S3. The region not to be 0 is an absorption region of the charge transfer complex.

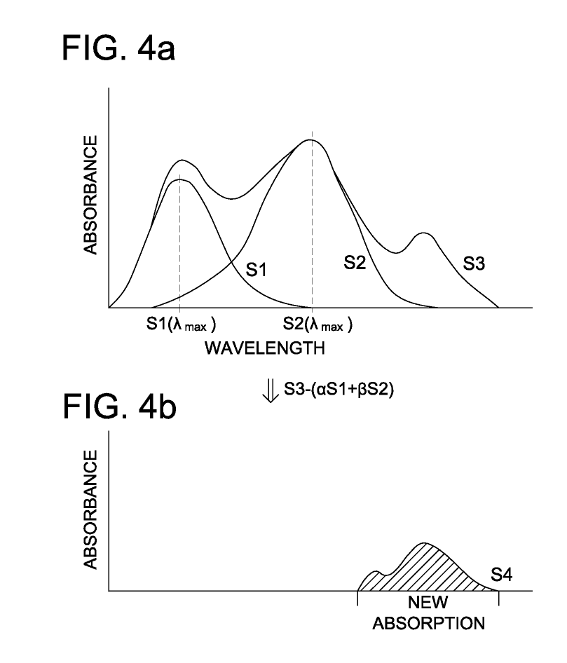

These are illustrated by FIGS. 4a and 4b. New absorption which is not found in S1 and S2 is observed by comparing the spectra S1 and S2 with a spectrum S3. An absorption spectrum S4 is obtained by subtracting S1 and S2 with a mixture ratio determined by the method described above from S3, and it is confirmed that a charge-transfer complex is formed.

<<In case no S2 skirt at shorter wavelength than λₘₐₓ of S1>>

S1 is subtracted from S3 so that λₘₐₓ of S1 becomes 0. It is determined that charge transfer complex is formed in case that a region not to be 0 is remained when S2 is subtracted from the remaining spectrum so that λₘₐₓ of S2 becomes 0. The wavelength region not to be 0 is an absorption region of the charge transfer complex, in this instance.

The term “region not to be 0” means that there be a wavelength region having absorbance of 0.2 or more in the above described measuring method.

The charge transfer complex is formed in case that the there is an absorption region of a charge transfer complex by calculating in this way.

An electron-donating compound exists preferably in excess than equimolar of the electron-donating compound and the electron-accepting compound in a system in their molar mixing ratio, whereby carrier transfer ability is improved, however when it is extremely in excess it is possible that absorption of the charge transfer complex becomes weak, sufficient amount of carrier does not generate and improvement of the conductivity is insufficient, since the electron-donating compound also works as a hole transfer material at dark time. On the other side, when the electron-accepting compound is added in excess it becomes possible that carrier trap sites or ratio of electron current on reversed direction increase, and conversion efficiency of a photo-electric conversion element. It is preferable a molar concentration ratio of the electron-donating compound and the electron-accepting compound is preferably electron-donating compound/electron-accepting compound=20/1 to 5/1, for a purpose of exhibiting an effect of the electron charge transfer complex as well as inhibiting the disadvantage by excess content of the electron-accepting compound.

Practical examples of the electron-donating compound used in this invention will be shown. However this invention is not restricted to these.

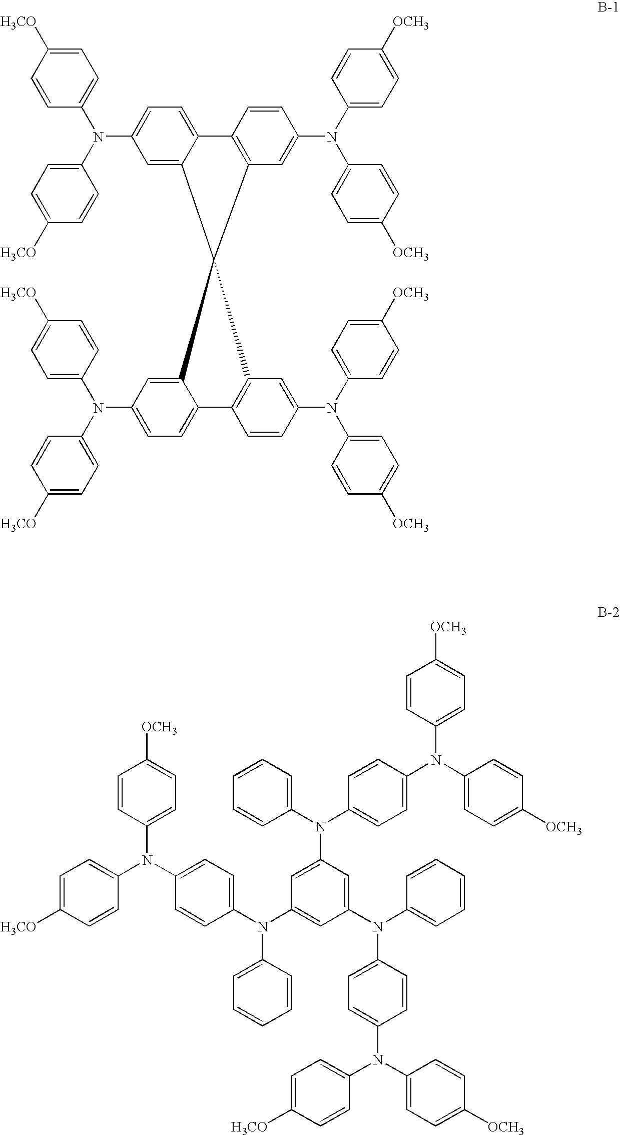

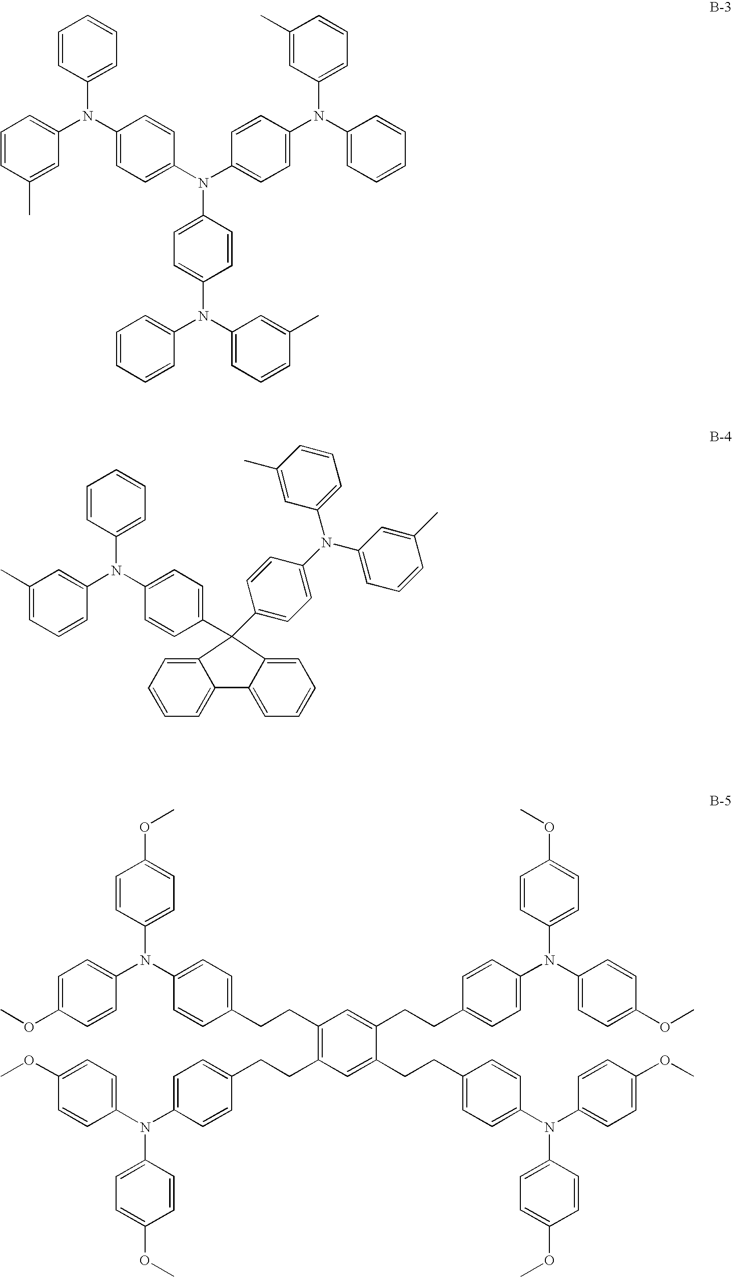

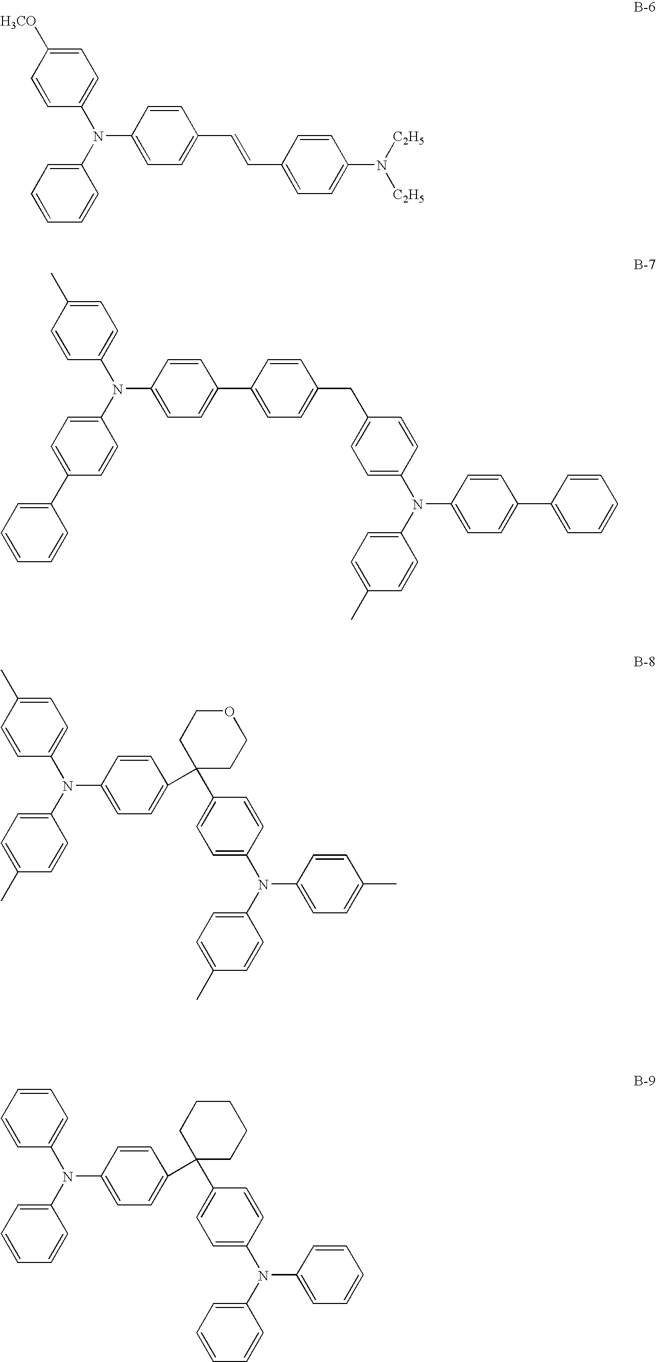

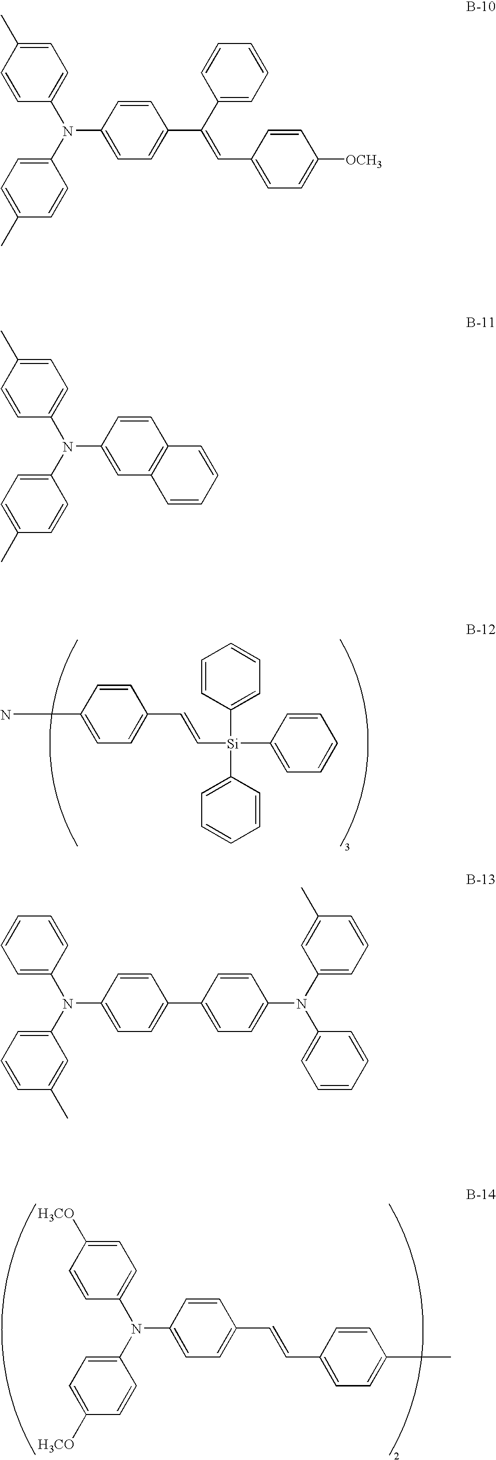

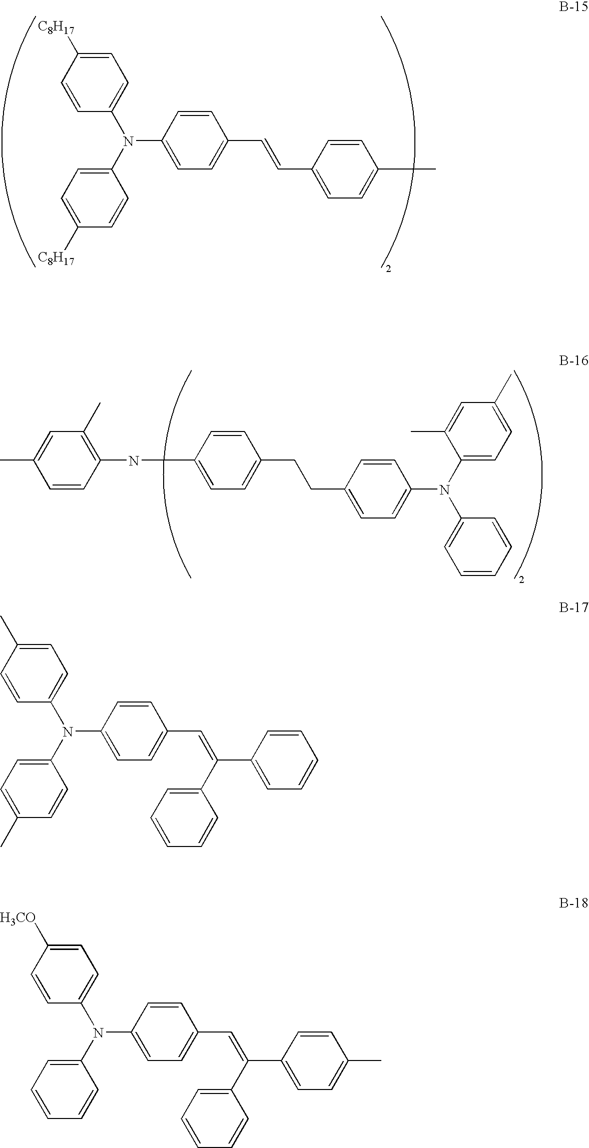

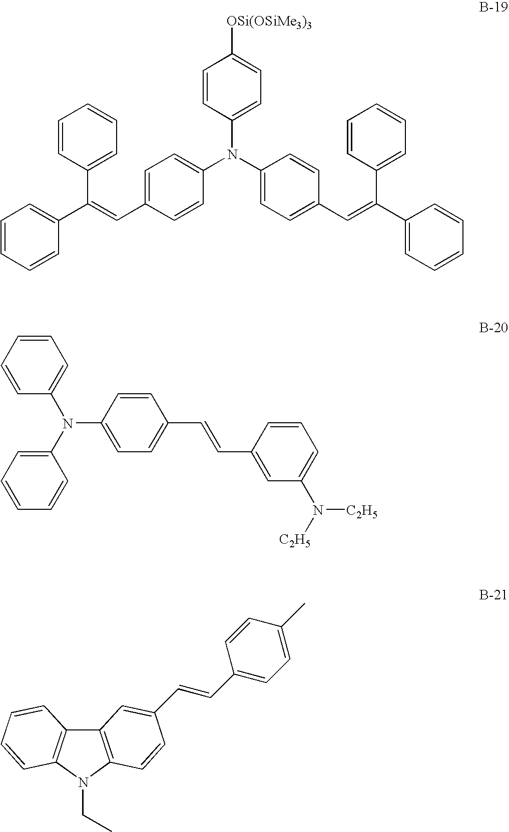

Practical examples of the electron-accepting compound used in this invention will be shown. However this invention is not restricted to these.

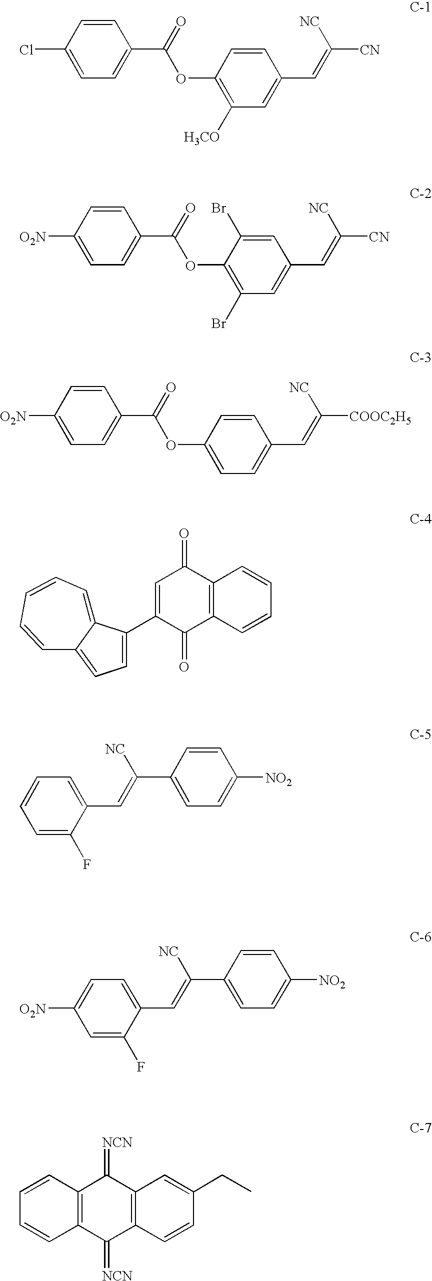

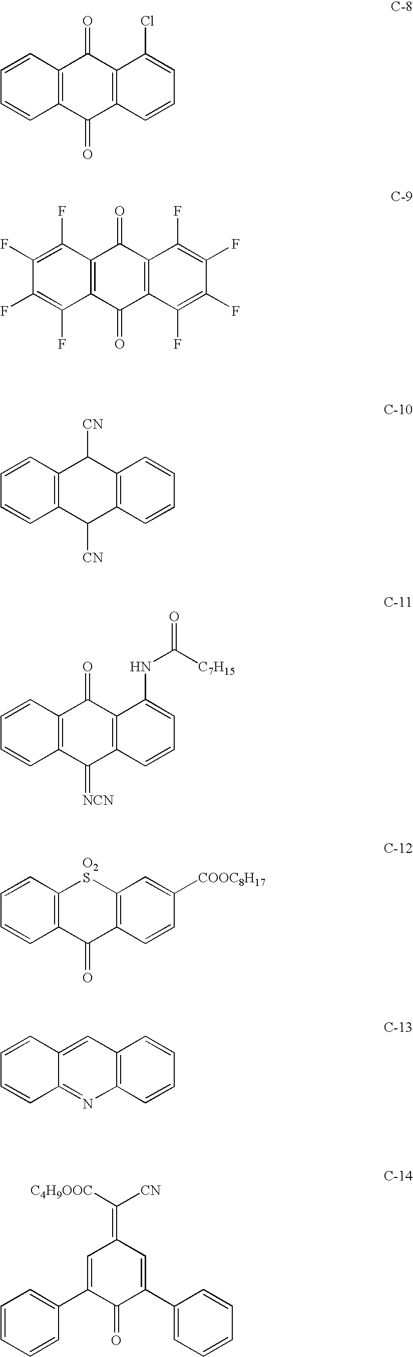

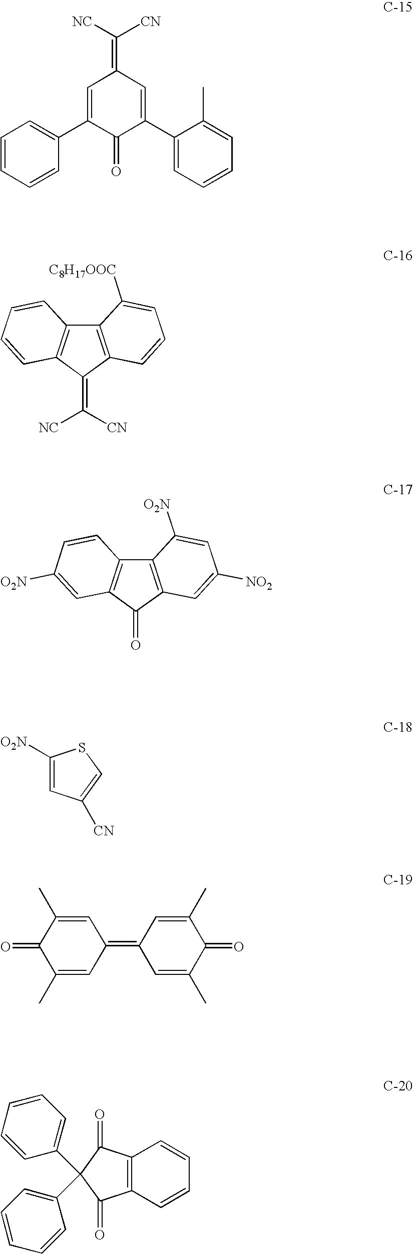

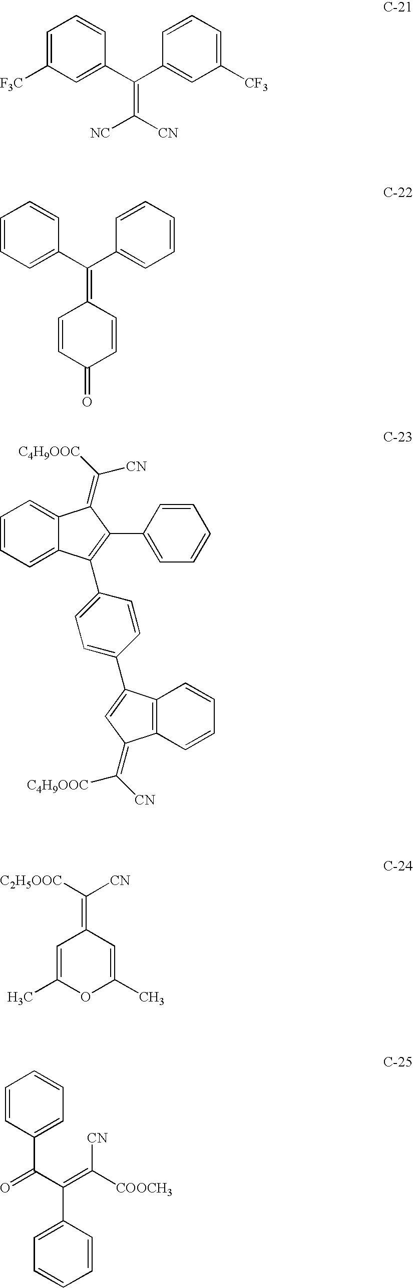

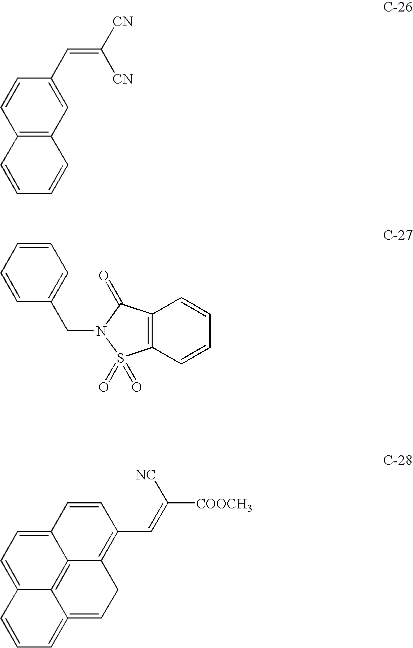

### (Manufacture of Charge Transfer Layer)

The charge transfer layer can be manufactured by a method wherein a mixed solution dissolving the electron-donating compound and the electron-accepting compound in a solvent capable of dissolving both molecules is coated on a semiconductor layer, then it is allowed to stand under atmosphere at room temperature, and it is dried via vacuum evacuation. Coating method is not particularly limited and is optionally selected according to viscosity of a material and a solution, examples of which includes various coating method such as dipping, dripping, doctor blade, spin coating, brush coating, spray coating and roll coater. The electron-donating compound and the electron-accepting compound may be dissolved after mixing them or, may be dissolved separately in solvents and then mixed.

Examples of solvent used in the process of forming the charge transfer layer includes organic solvent, for example, tetrahydrofuran, butylene oxide, chloroform, cyclohexane, chlorobenzene, acetone, and polar solvent such as various alcohols, non-proton solvent such as dimethyl formamide, acetonitrile and dimethoxy ethane, dimethylsulfoxide and hexamethylphosphoric acid triamide, and one of them or a combination of two or more kinds of them can be used.

Various additives such as N(PhBr)₃SbCl₆, Li[(CF₃SO₂)₂N] and 4-t-butylpyridine (TBP) may be added to the charge transfer layer, if necessary. Charge transfer layer can transfer charges more efficiently by virtue of adding these.

The additive such as an organic binder may be added if necessary. The organic binder which does not inhibit hole transfer extremely is preferably employed, for example, polyethylene oxide, polyvinylidene chloride, polycarbonate, polyacrylate, polymethylacrylate, polymethylmethacrylate polystyrene, polyvinylchloride and polysiloxane are employed.

Multi-layer can be formed by repeating processes such as coating and drying by heat.

A thickness of the charge transfer layer is not particularly limited, and, for example, is preferably 0.5 to 30 μm, more preferably 1 to 25 μm and particularly preferably 2 to 20 μm.

The photoelectric conversion element of this invention is composed of a semiconductor layer adsorbing dye in a semiconductor on the first electrode and the opposing second electrode arranged via a charge transfer layer. The first and the second electrodes are described.

As a first electrode utilized in the photoelectric converter of the present invention and the solar cell of the present invention, employed can be a conductive material such as a metal plate (such as platinum, gold, silver, copper, aluminum, rhodium and indium) and one having a structure in which conductive substance is provided on a non-conductive material such as a glass plate and a plastic film, wherein the conductive substance includes conductive metal oxides (such as indium-tin composite compound, those containing tin oxide doped with fluorine) and carbon. The thickness of the first electrode is preferably 0.0003 to 5 mm.

Further, the first electrode is preferably substantially transparent and to be substantially transparent means to have a transmittance of light of not less than 10%, preferably not less than 50% and most preferably not less than 80%. To obtain a transparent first electrode, it is preferable to provide a conductive layer containing conductive metal oxide on the surface of a glass plate or a plastic film. In the case of using a transparent first electrode, it is preferable to allow the light to introduce from the support side. In case of using opaque conductive layer, it is possible to make the second electrode transparent and is operated by introducing light from the second electrode side. Both the first and the second electrode may be transparent.

The surface resistance of a first electrode is preferably not more than 50 Ω/cm² and more preferably not more than 10 Ω/cm².

### (Second Electrode)

The second electrode used in this invention is described.

Those having conductivity are applicable for the second electrode, and any conductive materials are used. A metal film having good contact property with the charge transfer layer is preferable. Particularly preferable is a metal film of a chemically stable metal having small difference of work function from the charge transfer layer.

### Solar Cell

The solar cell is described. The solar cell of the invention and its circuit are designed most suitably for solar light as one embodiment of the photoelectric conversion element of the invention, and having a structure which performs most suitable photoelectric conversion when using solar light as a light source, namely, a structure of exposing a dye-sensitized semiconductor to solar light. In one preferred embodiment of the solar light of the invention, the foregoing semiconductor layer, the charge transfer layer and the second electrode are housed in a case and sealed or the whole of them is sealed with a resin.

When the solar cell of the invention is exposed to a solar light or an electromagnetic wave equivalent to a solar light, a sensitizing dye adsorbed on a semiconductor is excited by absorbing the exposed light or electromagnetic wave. An electron generated upon excitation moves to the semiconductor and then moves to then opposed electrode through an electrically first electrode to reduce the electron-donating compound such as aromatic amines contained in the charge transfer layer. On the other hand, the sensitizing dye which has allowed the electron to move to the semiconductor becomes an oxidized product but is reduced via an electron being supplied from the opposed electrode through the redox electrolyte of a charge transfer layer, returning to the original state. Thus, electrons flow, which constitutes a solar cell using the photoelectric conversion element of the invention.

### Examples

The invention will be further described with reference to example.

### Preparation of Photoelectric Conversion Element 1

An alkoxy titanium solution (TA-25/IPA dilution, supplied by Matsumoto Trading Co., Ltd.) was coated on a FTO electrode by a spin coating method. After standing at room temperature for 30 minutes, it was calcined at 450° C. to form a short circuit prevention layer. Subsequently, a commercially available titanium oxide paste (a particle diameter of 18 nm) was coated on the foregoing short-circuited prevention layer by a doctor blade method, followed by a heat treatment at 60° C. for 10 minutes and then a calcination treatment at 500° C. for 30 minutes to obtain a semiconductor substrate having a titanium oxide thin layer of a thickness of 5 μm provided on a conductive support.

The foregoing compound A-1 was dissolved in ethanol to prepare a 3×10⁻⁴ mol/L solution. The above-described semiconductor electrode substrate was immersed in this solution at room temperature for 3 hours to conduct an adsorption treatment of a sensitizing dye, then, washed with ethanol, followed by drying to form a semiconductor layer carrying a dye. Transmittance at 450 nm was 5%, and possessed absorption region. Transmittance at 530 nm was 45%, and possessed absorption region.

In a mixture solvent of chlorobenzene: acetonitrile of 19:1, 17 mmol/L of electron-donating compound B-1.10 mmol/L of an electron-accepting compound C-1.15 mmol/L of Li[(CF₃SO₂)₂N] and 50 mmol/L of BP were dissolved, the resultant was spin coated on the above described dye adsorbed photo-electric conversion electrode, was allowed to stand for 30 minutes at room temperature under atmosphere, was subjected to vacuum evacuation for 10 minutes, and a charge transfer layer was formed. Gold was evaporated with a thickness of 60 nm via vacuum deposition method to form a second electrode, and thus the photo-electric conversion element 1 was manufactured.

Absorbance at transmission wavelength 530 nm was 0.046 when absorption spectra of Compound B-1 and Compound C-1 were subtracted from the absorption spectrum of mixture of Compound B-1 and Compound C-1, and it was confirmed a charge transfer complex was formed by mixing Compound B-1 and Compound C-1.

### (Manufacture of Photo-Electric Conversion Element 20)

Photo-electric conversion element 20 was manufactured in the same manner as the photo-electric conversion element 1 except that Compound C-1 was not employed. Charge transfer complex was not formed in this Photo-electric conversion element 20.

### (Manufacture of Photo-Electric Conversion Elements 2 to 19, 21 and 22)

Photo-electric conversion elements 2 to 19, 21 and 22 were manufactured in the same manner as the photo-electric conversion element 1 except that the Compound B-1, the Compound C-1 and their molar concentration ratio were modified as shown in Table 1.

An absorption wavelength, transmission wavelength and its transmittance of the semiconductor layer, formation or not of the charge transfer complex, and absorbance of the charge transfer complex are shown in Table 1. The absorption wavelength, transmission wavelength and its transmittance of the semiconductor layer were measured for samples prepared by the same manner as the Photo-electric conversion elements 1 to 22, except that the electron-donating compound and the electron-accepting compound were not added and the second electrode of gold was not formed. Similarly, the absorbance of the charge-transfer complex was measured for samples prepared by the same manner as the Photo-electric conversion elements 1 to 22, except that the semiconductor layer and the second electrode of gold were not formed.

Transmission wavelength of the semiconductor layer is specific wavelength in the absorption region of the charge-transfer complex. The absorbance of the charge-transfer complex is a value measured at the transmission wavelength of the semiconductor layer. The transmittance and absorbance were measured by a spectrometer (Trade name of U-3500, manufactured by Hitachi Ltd.)

TABLE 1

| | | Absorption | | Transmission | | | | | | | |
|---|---|---|---|---|---|---|---|---|---|---|---|
| | | wavelength and | | wavelength and | | | | | Charge transfer complex | | |
| Photo- | Dye in | transmittance | | transmittance | | Electron- | Electron- | | Formation | Absorbance | |
| electric | semi- | Wave- | Trans- | Wave- | Trans- | donating | accepting | | of charge | at trans- | |
| conversion | conductor | length | mittance | length | mittance | compound | compound | | transfer | mission | |
| element | layer | (nm) | (%) | (nm) | (%) | (B) | (C) | B:C | complex | wavelength | Remarks |
| 1 | A-1 | 450 | 5 | 530 | 45 | B-1 | C-1 | 17:1 | YES | 0.046 | Invention |
| 2 | A-2 | 400 | 10 | 465 | 45 | B-3 | C-1 | 17:1 | YES | 0.041 | Invention |
| 3 | A-2 | 460 | 20 | 510 | 45 | B-1 | C-5 | 17:1 | YES | 0.046 | Invention |
| 4 | A-3 | 480 | 30 | 540 | 45 | B-1 | C-14 | 17:1 | YES | 0.081 | Invention |
| 5 | A-4 | 450 | 35 | 495 | 45 | B-3 | C-2 | 17:1 | YES | 0.056 | Invention |
| 6 | A-5 | 405 | 40 | 470 | 45 | B-3 | C-1 | 17:1 | YES | 0.046 | Invention |
| 7 | A-6 | 535 | 45 | 600 | 45 | B-1 | C-15 | 17:1 | YES | 0.036 | Invention |
| 8 | A-1 | 450 | 5 | 510 | 35 | B-1 | C-5 | 17:1 | YES | 0.046 | Invention |
| 9 | A-1 | 450 | 5 | 540 | 55 | B-1 | C-14 | 17:1 | YES | 0.071 | Invention |
| 10 | A-1 | 450 | 5 | 550 | 65 | B-5 | C-16 | 17:1 | YES | 0.046 | Invention |
| 11 | A-1 | 450 | 5 | 570 | 75 | B-6 | C-15 | 17:1 | YES | 0.041 | Invention |
| 12 | A-1 | 450 | 5 | 580 | 85 | B-13 | C-15 | 17:1 | YES | 0.051 | Invention |
| 13 | A-1 | 450 | 5 | 590 | 95 | B-18 | C-15 | 17:1 | YES | 0.032 | Invention |
| 14 | A-1 | 450 | 5 | 530 | 45 | B-1 | C-1 | 20:1 | YES | 0.032 | Invention |
| 15 | A-1 | 450 | 5 | 530 | 45 | B-1 | C-1 | 5:1 | YES | 0.187 | Invention |
| 16 | A-1 | 450 | 5 | 530 | 45 | B-1 | C-1 | 24:1 | YES | 0.022 | Invention |
| 17 | A-1 | 450 | 5 | 530 | 45 | B-1 | C-1 | 3:1 | YES | 0.301 | Invention |
| 18 | A-12 | 405 | 30 | 465 | 80 | B-3 | C-1 | 17:1 | YES | 0.073 | Invention |
| 19 | A-12 | 405 | 30 | 495 | 98 | B-3 | C-2 | 17:1 | YES | 0.016 | Invention |
| 20 | A-1 | 450 | 5 | 530 | 45 | B-1 | — | — | NO | — | Comparative |
| 21 | A-1 | 450 | 5 | 565 | 70 | B-1 | C-19 | 17:1 | NO | 0.005(*) | Comparative |
| 22 | A-1 | 450 | 5 | 590 | 95 | B-17 | C-1 | 17:1 | NO | 0.002(*) | Comparative |

(*)Maximum value of the spectrum obtained according to a method of measuring absorption of the charge transfer complex.

Similarly to photo-electric conversion element 1, it was confirmed a charge transfer complex was formed by mixing the electron-donating compound and an electron-accepting compound in each photo-electric conversion elements 2 to 19.

Absorbance at transmission wavelength 565 nm was 0.005 when absorption spectra of Compound B-1 and Compound C-19 were subtracted from the absorption spectrum of mixture of Compound B-1 and Compound C-19, and it was not confirmed a charge transfer complex was formed by mixing Compound B-1 and Compound C-19, in Photo-electric conversion Element 21. Similarly it was not confirmed a charge transfer complex was formed in Photo-electric conversion Element 22.

### <<Evaluation of Photo-Electric Conversion Element>>

### (Electricity Generation Performance)

Evaluation of the electricity generation performance of the manufactured photoelectric conversion elements was conducted by exposing to pseudo solar light having 100 mW/cm² from Xenon lamp through AM filter (1M-1.5) by employing a solar simulator (WXS-85-H, manufactured by Wacom Electric Co., Ltd). Current-potential property of the photoelectric conversion elements was measured at room temperature by employing an I-V tester, and short-circuit current (I_{sc}), open-circuit voltage (V_{oc}), and form factor (FF) were obtained. A photoelectric conversion efficiency η(%) was obtained by employing these. The photoelectric conversion efficiency before and after the ozone exposure test of 10 ppm for 30 minutes were compared.

The evaluation results are shown in Table 2.

TABLE 2

| Photo- | | | | Photoelectric conversion | | |
|---|---|---|---|---|---|---|
| electric | | | | efficiency (%) | | |
| conversion | Voc | Isc | Form | Before | After | |
| element | (V) | (mA/cm2) | factor | Exposure A | Exposure B | B/A |
| 1 | 0.853 | 7.6 | 0.60 | 3.9 | 3.6 | 0.92 |
| 2 | 0.865 | 7.2 | 0.61 | 3.8 | 3.5 | 0.92 |
| 3 | 0.860 | 7.4 | 0.58 | 3.7 | 3.4 | 0.92 |
| 4 | 0.858 | 7.5 | 0.56 | 3.6 | 3.4 | 0.94 |
| 5 | 0.862 | 7.0 | 0.57 | 3.5 | 3.2 | 0.91 |
| 6 | 0.867 | 6.8 | 0.58 | 3.4 | 3.2 | 0.94 |
| 7 | 0.855 | 7.8 | 0.55 | 3.7 | 3.4 | 0.92 |
| 8 | 0.857 | 6.8 | 0.57 | 3.3 | 3.0 | 0.91 |
| 9 | 0.849 | 7.9 | 0.56 | 3.8 | 3.5 | 0.92 |
| 10 | 0.844 | 7.5 | 0.59 | 3.7 | 3.4 | 0.92 |
| 11 | 0.839 | 7.6 | 0.60 | 3.8 | 3.5 | 0.92 |
| 12 | 0.862 | 7.7 | 0.59 | 3.9 | 3.5 | 0.90 |
| 13 | 0.861 | 7.6 | 0.55 | 3.6 | 3.3 | 0.92 |
| 14 | 0.851 | 7.4 | 0.59 | 3.7 | 3.5 | 0.95 |
| 15 | 0.840 | 8.1 | 0.56 | 3.8 | 3.5 | 0.92 |
| 16 | 0.846 | 7.1 | 0.55 | 3.3 | 3.0 | 0.91 |
| 17 | 0.820 | 8.3 | 0.47 | 3.2 | 2.9 | 0.91 |
| 18 | 0.821 | 7.8 | 0.54 | 3.5 | 3.2 | 0.91 |
| 19 | 0.801 | 8.2 | 0.48 | 3.2 | 2.8 | 0.88 |
| 20 | 0.845 | 5.0 | 0.53 | 2.2 | 1.5 | 0.68 |
| 21 | 0.847 | 5.0 | 0.53 | 2.2 | 1.4 | 0.64 |
| 22 | 0.849 | 4.3 | 0.55 | 2.0 | 1.4 | 0.70 |

The photoelectric conversion elements 1 to 19 have all high photoelectric conversion efficiency in comparison with the comparative photoelectric conversion elements 20 to 22. It is understood that the ratio of the photoelectric conversion efficiency (B/A) before and after the ozone exposure is high and the durability is superior. Therefore, high performance photo-electric conversion elements can be provided by employing two types compounds forming a charge transfer complex having an absorption at transmission wavelength of the semiconductor layer.

1. A photoelectric conversion element comprising a semiconductor layer having light absorption in an absorption wavelength region at least 350 to 1,000 nm and a charge transfer layer provided between a first electrode and a second electrode, wherein
the semiconductor layer has transmission wavelength in the absorption wavelength region,
the charge transfer layer comprises a charge transfer complex formed by an electron-donating compound and an electron-accepting compound, and the charge-transfer complex has absorption wavelength in the transmission wavelength of the semiconductor layer.

2. The photoelectric conversion element of claim 1, wherein a transmittance of the semiconductor layer at the transmission wavelength is not less than 40%.

3. The photoelectric conversion element of claim 1, wherein a molar concentration ratio of the electron-donating compound to the electron-accepting compound forming the charge transfer complex is
electron-donating compound/electron-accepting compound=20/1 to 5/1.

4. The photoelectric conversion element of claim 1, wherein the electron-donating compound is selected from the group consisting of a phenyl amine compound, a triphenyl methane compound, a carbazole compound, a phenol compound and a tetrathiafulvalene compound.

5. The photoelectric conversion element of claim 1, wherein the electron-accepting compound is selected from the group consisting of a quinine compound, a fluorenone compound, a chloranil compound, a bromanil compound and a tetracyanoquinodimethane compound.

6. The photoelectric conversion element of claim 1, wherein a thickness of the charge transfer layer is 0.5 to 30 μm.

7. The photoelectric conversion element of claim 6, wherein a thickness of the charge transfer layer is 1 to 25 μm.

8. The photoelectric conversion element of claim 1, wherein the semiconductor layer comprises a dye.

9. The photoelectric conversion element of claim 8, wherein the dye has a carboxy group in its molecule.

10. The photoelectric conversion element of claim 1, wherein the first electrode is transparent.

11. The photoelectric conversion element of claim 1, wherein a surface resistance of the first electrode is preferably not more than 50 Ω/cm².

12. The photoelectric conversion element of claim 11, wherein a surface resistance of the first electrode is preferably not more than 10 Ω/cm².

13. A solar cell containing the photoelectric conversion element of claim 1.
